(19) United States
(12) Patent Application Publication
(10) Pub. No.: US 2025/0290996 A1
(43) Pub. Date: Sep. 18, 2025

(54) DEVICE AND METHOD FOR DETECTING A CONDITION OF SECONDARY BATTERY

(71) Applicants: SAMSUNG SDI CO., LTD., Yongin-si (KR); IUCF-HYU (Industry-University Cooperation Foundation Hanyang University), Seoul (KR)

(72) Inventors: Hee Seon CHOI, Yongin-si (KR); Jong-Won LEE, Seoul (KR); Hong Rim SHIN, Seoul (KR); Youngugk KIM, Yongin-si (KR); Jaehou NAH, Yongin-si (KR); Ilyoung CHOI, Yongin-si (KR); Deok-Hyun KIM, Yongin-si (KR)

(21) Appl. No.: 19/071,534

(22) Filed: Mar. 5, 2025

(30) Foreign Application Priority Data
Mar. 12, 2024 (KR) 10-2024-0034639

(51) Int. Cl. G01R 31/392; G01R 31/367; G01R 31/382; H01M 10/48

(52) U.S. Cl. CPC G01R 31/392; G01R 31/367; G01R 31/382; H01M 10/48

(57) ABSTRACT

A device and a method for detecting a condition (e.g., deterioration) of a secondary battery are disclosed. A device for detecting a condition of a secondary battery according to embodiments includes: a measurement device configured to measure a current of the secondary battery; and a control device configured to obtain a first current curve representing a relationship between a charging capacity and the current of the secondary battery based on a value of the current of the secondary battery measured during a charging phase, and detect the condition of the secondary battery based on a first position of a first point in the first current curve.

### CROSS-REFERENCE TO RELATED APPLICATION

The present application claims priority to and the benefit of Korean Patent Application No. 10-2024-0034639, filed on Mar. 12, 2024, at the Korean Intellectual Property Office, the entire disclosure of which is incorporated herein by reference.

### BACKGROUND

### 1. Field

The present disclosure relates to a device and a method for detecting a condition of a secondary battery.

### 2. Description of the Related Art

Unlike a primary battery that is not designed to be charged, a secondary (or rechargeable) battery is designed to be repeatedly discharged and recharged. A low-capacity secondary battery may be used in a portable small electronic device such as a smart phone, a feature phone, a laptop computer, a digital camera, or a camcorder, while a large-capacity secondary battery may be used as a power source for driving a motor of a hybrid vehicle, an electric vehicle, or the like, and as a an electric power storage device (e.g., home and/or utility scale power storage). The secondary battery generally includes an electrode assembly including a positive electrode and a negative electrode, a case accommodating the electrode assembly, and an electrode terminal connected to the electrode assembly, and the like.

A lithium secondary battery is a secondary battery including an active material capable of intercalation and deintercalation of a lithium ion. If the lithium secondary battery is repeatedly and rapidly charged, some lithium ions may be precipitated as a lithium metal so that lithium precipitation may gradually accumulate on a surface of the negative electrode. If an amount of the lithium precipitation is greater than or equal to a certain level, an amount of lithium available for energy storage in the lithium secondary battery may decrease and resistance may increase so that performance of the battery is deteriorated. Additionally, the precipitated lithium metal may cause a short circuit between the positive electrode and the negative electrode to increase a risk of fire.

The above-described information disclosed in the background of this disclosure is for improving understanding of the background of the present disclosure, and thus may include information that does not constitute related (or prior) art.

### SUMMARY

One or more embodiments of the present disclosure are directed to a device and a method for diagnosing or detecting a condition including deterioration of a secondary battery that may diagnose (e.g., non-destructively diagnose) a deterioration state of the secondary battery due to lithium precipitation during rapid charging.

However, a technical problem to be solved by the present disclosure is not limited to the problem, and other technical problems not mentioned may be clearly understood by those skilled in the art from a description of the present disclosure below.

A device for detecting a condition of a secondary battery according to embodiments for solving the technical problem includes: a measurement device configured to measure a current of the secondary battery; and a control device configured to obtain a first current curve representing a relationship between a charging capacity and the current of the secondary battery based on a value of the current of the secondary battery measured during a first charging phase, and detect the condition of the secondary battery based on a first position of a first point in the first current curve.

The control device may be further configured to perform a mathematical computation to the first current curve to obtain a second current curve, and obtain the first position where the first point occurs in the first current curve based on a second position where a second point is detected in the second current curve. In some embodiments, the mathematical computation includes applying differential calculus to the first current curve, wherein the second current curve includes a differential current curve, the first point includes an inflection point in the first current curve, and the second point includes a peak point in the differential current curve.

In some embodiments, the first point includes an inflection point in the first current curve. The first position of the inflection point may indicate a charging capacity value at which the inflection point occurs in the first current curve.

In some embodiments, the condition of the secondary battery includes deterioration of the secondary battery. The control device may be further configured to perform an operation for obtaining the first current curve and detecting the first position of the first point in the first current curve for a plurality of charging phases including the first charging phase. The control device may be further configured to diagnose occurrence of the deterioration of the secondary battery by comparing a first charging capacity value where the first point occurs in the first current curve of the first charging phase with a second charging capacity value where the first point occurs in the first current curve of a previous charging phase.

The control device may be further configured to diagnose that the deterioration of the secondary battery occurs based on the first charging capacity value being greater than the second charging capacity value.

In some embodiments, the condition of the secondary battery includes deterioration of the secondary battery. The control device may be further configured to detect that a deterioration state of the secondary battery reaches a dangerous stage based on an amount of change in the first position of the inflection point.

The control device may be further configured to perform an operation for obtaining the first current curve and the first position of the first point in the first current curve for a plurality of charging phases including the first charging phase, and calculate an amount of change in the first position by subtracting a second charging capacity value where the first point occurs in the first current curve of a previous charging phase from a first charging capacity value where the first point occurs in the first current curve of the first charging phase.

The control device may be further configured to detect that the deterioration state of the secondary battery reaches the dangerous stage based on detecting the amount of change in the first position decreases compared to a second amount of change associated with the previous charging phase.

The control device may be further configured to detect that the deterioration state of the secondary battery reaches the dangerous stage based on detecting that the amount of change in the first position decreases a set number of times during a plurality of charging phases.

A battery pack according to one or more embodiments of the present disclosure includes: a secondary battery; and the device for detecting the condition of the secondary battery.

A method for detecting a condition of the secondary battery according to one or more embodiments of the present disclosure includes: obtaining a first current curve representing a relationship between a charging capacity and a current of the secondary battery based on a value of the current of the secondary battery measured during a first charging phase; obtaining a first position of a first point in the first current curve; and detecting the condition of the secondary battery based on the first position of the first point.

The obtaining of the first position of the first inflection point may include: performing a mathematical computation to the first current curve to obtain a second current curve; detecting a second point in the second current curve; and obtaining the first position of the first point based on a second position at which the second point is detected in the second current curve.

The first position of the first point may indicate a charging capacity value at which an inflection point occurs in the first current curve.

Obtaining the first current curve and obtaining the first position of the first point may be performed for a plurality of charging phases in the method for detecting the condition. The detecting of the condition may include detecting deterioration of the secondary battery by comparing a first charging capacity value where the first point occurs in the first current curve of the first charging phase with a second charging capacity value where the first point occurs in the first current curve of a previous charging phase.

The detecting the deterioration of the secondary battery is based on the first charging capacity value being greater than the second charging capacity value.

Obtaining the first current curve and obtaining the first position of the first point may be performed for a plurality of charging phases including the first charging phase in the method for detecting the condition. The detecting of the condition may include detecting that a deterioration state of the secondary battery reaches a dangerous stage based on an amount of change in the first position of the inflection point.

The method may further include calculating the amount of change in the first position by subtracting a second charging capacity value where the inflection point occurs in the first current curve of a previous charging phase from a first charging capacity value where the first point occurs in the first curve of the first charging phase.

The detecting of the deterioration state may include determining that the deterioration state of the secondary battery reaches the dangerous stage based on detecting that the amount of change in the first position decreases compared to a previous amount of change.

The detecting of the deterioration state may include determining that the deterioration state of the secondary battery reaches the dangerous stage based on detecting that the amount of change in the first position decreases a set number of times during a plurality of charging phases.

According to one or more embodiments of the present disclosure, a condition such as a deterioration state of a secondary battery due to lithium precipitation during charging (e.g., rapid charging) may be diagnosed (e.g., in a non-destructive manner).

However, an effect that may be obtained through the present disclosure is not limited to the above-described effect, and other technical effects not mentioned may be clearly understood by those skilled in the art from a description of the present disclosure below.

### BRIEF DESCRIPTION OF THE DRAWINGS

The drawings attached to the present specification illustrate embodiments of the present disclosure and further describe aspects and features of the present disclosure together with a detailed description of the present disclosure to be described later. Thus, the present disclosure should not be construed as being limited to the drawings.

FIG. 1 is a block diagram of a device for diagnosing deterioration of a secondary battery according to some embodiments.

FIG. 2A shows examples of current curves obtained in a constant voltage charging section in which the secondary battery is rapidly charged with a constant current-constant voltage.

FIG. 2B shows examples of differential current curves obtained by differentiating the current curves of FIG. 2A.

FIG. 3 is a flow diagram of a process for diagnosing deterioration of the secondary battery according to some embodiments.

### DETAILED DESCRIPTION

Below, embodiments of the present disclosure will be described in detail with reference to the attached drawings. A term or a word used in the present specification and claims should not be construed as limited to its usual or dictionary meaning and should be interpreted as a meaning and a concept conforming to a technical idea of the present disclosure based on a principle that an inventor may be his/her own lexicographer to properly define a concept of the term to describe his or her invention in the best way. Thus, the embodiments described in the present specification and the configurations shown in the drawings are only examples of embodiments of the present disclosure and do not represent all of the technical ideas, aspects, and features of the present disclosure. Accordingly, it should be appreciated that there may be various equivalents and variations that may replace or modify the embodiments described herein at a time at which the present application is filed.

A person of ordinary skill in the art would appreciate, in view of the present disclosure in its entirety, that a feature of embodiments of the present disclosure may be combined or combined with one or more other features, partially or entirely, and may be technically interlocked and operated in various suitable ways, and an embodiment may be implemented independently of one or more other embodiments, or in conjunction with the one or more other embodiments in a suitable manner, unless expressly stated or implied otherwise.

A term “comprises”, “includes”, “comprising”, or “including” when used in the present specification, specifies presence of a shape, a number, a step, an operation, a member, an element, and/or a group thereof, but does not preclude presence or addition of one or more other shapes, one or more other numbers, one or more other operations, one or more other members, one or more other elements, and/or groups thereof. Further, a use of “may” when the embodiments of the present disclosure described are described refers to “one or more embodiments of the present disclosure”.

Additionally, to help understanding of the present disclosure, the attached drawings may not be shown at an actual scale, and dimensions of some components may be exaggerated for clarity of illustration in the drawings. In addition, the same reference number may be assigned to the same component in different embodiments.

When it is described that two objects are identical, this means that the objects are “substantially identical”. Therefore, the substantially identical objects may include objects having deviations considered low in the art, for example, deviations within 5%. Additionally, when it is described that certain parameters are uniform in a predetermined region, this may mean that the parameters are uniform in terms of an average.

Although terms “first”, “second”, and the like are used to describe various components, the components are not limited by the terms. The terms are used to distinguish one component from another component, and unless otherwise stated, the first component may be the second component.

Throughout the specification, unless otherwise stated, each component may be singular or plural. For example, the singular forms “a” and “an” are intended to include the plural forms as well, unless the context clearly indicates otherwise.

Disposing (or locating or positioning) any component at an “upper portion (or lower portion)” of or “on (or below)” another component may mean not only that the component is disposed (or located or positioned) in contact with an upper surface (or lower surface) of the other component but also that another component may be interposed between the other component and the component disposed on (or below) the other component.

In addition, spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

Additionally, when it is described that a component, element, or layer (collectively referenced as “component”) is “on,” “connected to”, “coupled to”, or “accessed by” another component, it may be directly on, connected, coupled, or accessed to the other component, but it should be understood that another component may be “interposed” between the components or the components are “on,” “connected to”, “coupled to”, or “accessed by” through another component. In addition, when one portion is referred to as being electrically coupled or connected to another portion, this includes not only a case where the one portion is directly coupled to the other portion, but also includes a case where the one portion is coupled to the other portion via an intervening element.

Throughout the specification, when referring to “A and/or B”, it means A, B, or A and B, unless specifically stated to the contrary. That is, the term “and/or” includes all or any combination of a plurality of items listed. When referring to “C to D”, unless otherwise specified, it means that it is greater than or equal to C and less than or equal to D.

As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

Typically, a reaction speed of a carbon negative electrode may be slower than that of a positive electrode during charging (e.g., fast charging) of a secondary battery using lithium, so that a current flowing in the secondary battery during charging (e.g., constant voltage charging) is determined by an overvoltage of the negative electrode. As the constant voltage charging is performed, the overvoltage of the negative electrode of the secondary battery may gradually decrease so that the current flowing through the secondary battery may also gradually decrease. In an embodiment in which a charging voltage is fixed, a change in the overvoltage of the negative electrode over time of the secondary battery may be determined by a change in a potential of the positive electrode. Therefore, if an inflection point occurs in a potential curve of the positive electrode of the secondary battery while the constant voltage charging is performed, an inflection point may also occur in a current curve of the secondary battery.

If a potential of the negative electrode of the secondary battery is decreased to 0 V (vs. Li/Li⁺) or less during rapid charging, lithium may be precipitated on a surface of the negative electrode of the secondary battery. This lithium precipitation may increase as the potential of the negative electrode of the secondary battery decreases. If the lithium precipitation of the secondary battery increases, a resistance of the battery may increase because the surface of the negative electrode is deactivated or a lithium ion transport path is blocked due to the lithium precipitation. If the resistance of the battery increases, the constant voltage charging may start in a state where a state of charge (SOC) of the positive electrode is lower after the constant current charging. Therefore, in some embodiments, if the resistance of the secondary battery increases, the inflection point of the current curve that occurs during the constant voltage charging may be detected at a gradually high charging capacity.

As a charging and discharging cycle progresses, an amount of active lithium may gradually decrease due to the lithium precipitation of the secondary battery, and the potential of the negative electrode may gradually increase during the charging. In some embodiments, an amount of the lithium precipitation of the secondary battery may gradually decrease so that an increase in the resistance of the battery is alleviated. In some embodiments, a degree of change in the charging capacity at which the inflection point is detected in the current curve may be reduced.

A device for diagnosing deterioration of a secondary battery according to embodiments of the present disclosure may include detecting a characteristic or condition of the lithium secondary battery to detect the above-described inflection point from the current curve obtained from the secondary battery during a charging phase (e.g., a constant voltage charging section or phase), and compare charging capacities of the secondary battery in which the inflection point is detected. In some embodiments, it is possible to diagnose deterioration of the secondary battery based on the comparing of the charging capacities.

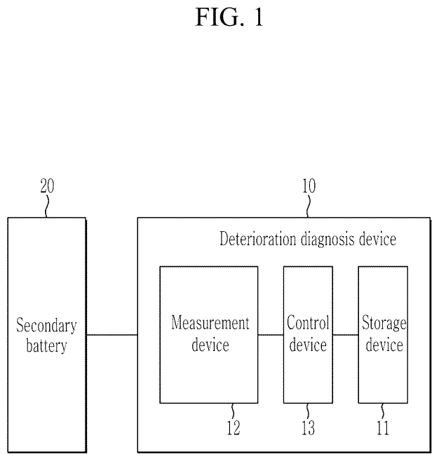

FIG. 1 is a block diagram of a device for diagnosing or detecting a condition of the secondary battery according to the embodiments. Hereinafter, the condition that is detected by the device is described as deterioration of the secondary battery, and the device is referred to as a deterioration diagnosis device 10.

Referring to FIG. 1, the deterioration diagnosis device 10 according to the embodiments of the present disclosure may include a storage device 11, a measurement device 12, and a control device 13.

The storage device 11 may store various information, various data, and the like, processed by the deterioration diagnosis device 10. The storage device 11 may store a program (or computer program instructions) for operating the control device 13. In some embodiments, the storage device 11 may include memory such as volatile memory and/or non-volatile memory.

The measurement device 12 may measure a state value such as an electric current, a voltage, or the like of the secondary battery 20, and may transfer the measured state values to the control device 13. For example, the measurement device 12 may measure a current flowing through the secondary battery 20 using a shunt resistor or the like, and may transfer a signal corresponding to the measured current value to the control device 13.

The control device 13 may control an overall operation of the deterioration diagnosis device 10.

The control device 13 may collect the current value measured from the secondary battery 20 through the measurement device 12 during the constant voltage charging section in which the secondary battery 20 is charged at a constant voltage.

The control device 13 may obtain the current curve during the constant voltage charging section using current values collected during the constant voltage charging section. For example, the current curve may represent a change of the current according to the charging capacity of the secondary battery 20.

As described above, during rapid charging, the inflection point may occur in the current curve of the constant voltage charging section. In order to easily detect a position where the inflection point occurs in the current curve, the control device 13 may obtain a second current curve (e.g., a differential current curve) that represents a current change rate (e.g., an instantaneous current change rate) according to the charging capacity by performing a mathematical computation including applying differential calculus to the current curve (hereinafter referred to as “differentiating the current curve”). If the inflection point is present in the current curve, the inflection point in the current curve may become clearer as a peak point in the differential current curve.

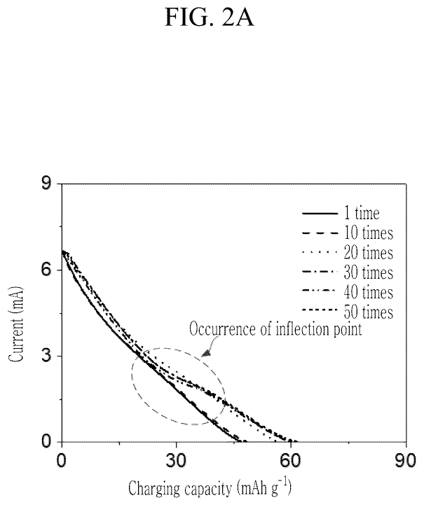

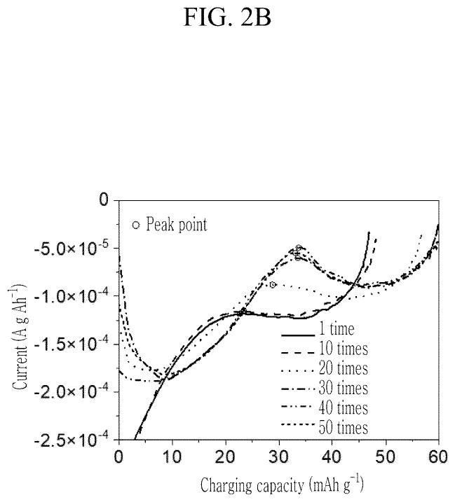

FIG. 2A shows examples of current curves obtained in the constant voltage charging section in which the secondary battery 20 is rapidly charged with a constant current-constant voltage, and FIG. 2B shows examples of differential current curves obtained by differentiating the current curves of FIG. 2A. In the examples of FIG. 2A and FIG. 2B, the respective curves are results obtained by performing a cycle of rapid charging of the secondary battery 20 1 time, 10 times, 20 times, 30 times, 40 times, and 50 times. Referring to FIG. 2A and FIG. 2B, inflection points of the current curves of FIG. 2A may be converted into peak points of the differential current curves of FIG. 2B.

In the embodiment where the differential current curve is obtained, the control device 13 may detect the peak point from the differential current curve. For example, the control device 13 may obtain a charging capacity value at which the peak point is detected at the differential current curve. In some embodiments, the peak point in the differential current curve corresponds to the inflection point in the current curve, and the charging capacity value at which the peak point is detected in the differential current curve may correspond to a charging capacity value at which the inflection point occurs in the current curve. In some embodiments, the control device 13 may obtain the charging capacity value at which the peak point is detected in the differential current curve as position information of the inflection point in the current curve. The control device 13 may obtain position information of the inflection point in the above-described manner for one or more (e.g., each) constant voltage charging section of the secondary battery 20, and may store the position information of the inflection point in the storage device 11.

The control device 13 may diagnose a deterioration state of the secondary battery 20 based on the position information of the inflection point obtained in the one or more (e. g, each) constant voltage charging section.

In some embodiments, the control device 13 may diagnose occurrence of deterioration of the secondary battery 20 by monitoring a change in the position where the inflection point occurs in the current curve. The control device 13 may compare a position where the inflection point occurs in the current curve (e.g., the charging capacity value where the inflection point occurs in the current curve) of a current constant voltage charging section with a position where the inflection point occurs in the current curve of a previous constant voltage charging section. If the charging capacity value where the inflection point occurs in the current curve increases compared to that of the previous constant voltage charging section, the control device 13 may determine deterioration of the secondary battery 20 due to an increase in the lithium precipitation and the resistance of the battery. For example, if the charging capacity value where the inflection point occurs in the current curve of the current constant voltage charging section is greater than the charging capacity value where the inflection point occurs in the current curve of the previous constant voltage charging section, the control device 13 may determine deterioration of the secondary battery 20. If deterioration of the secondary battery 20 is detected, the control device 13 may output a warning signal or other notification indicating the detection of the deterioration of the secondary battery 20 to warn a user. The control device 13 may transfer the warning signal warning of the deterioration of the secondary battery 20 to an upper control device (e.g., a vehicle controller of a vehicle on which the secondary battery 20 is mounted, or the like). In some embodiments, the upper control device may take action based on the warning signal such as, for example, stopping operation of a vehicle or device in which the battery is mounted.

As a charging and discharging cycle progresses, an amount of active lithium may gradually decrease due to the lithium precipitation of the secondary battery 20, and a potential of the negative electrode may gradually increase during the charging. In some embodiments, if the deterioration of the secondary battery 20 intensifies, an amount of the lithium precipitation of the secondary battery may gradually decrease so that an increase in the resistance of the battery is alleviated. In some embodiments, a degree of change in the charging capacity value at which the inflection point is detected in the current curve may be reduced. In some embodiment, the control device 13 may monitor an amount of change in the position where the inflection point occurs in the current curve to diagnose whether the deterioration of the secondary battery 20 satisfies a maximum threshold level of deterioration. If the amount of change in the position where the inflection point occurs in the current curve decreases, the control device 13 may determine that the deterioration of the secondary battery 20 satisfies the maximum threshold level of deterioration. When charging capacity values where the inflection point occurs in current curves of consecutive first, second, and third constant voltage charging sections are first, second, and third capacity values, the control device 13 may determine that the deterioration of the secondary battery 20 reaches the maximum threshold level of deterioration if a condition of “the first capacity value<the second capacity value<the third capacity value,” and a condition of “(the second capacity value−the first capacity value)>(the third capacity value−the second capacity value)” are satisfied. If it is determined that the deterioration of the secondary battery 20 satisfies the maximum threshold level of deterioration, the control device 13 may determine that the deterioration of the secondary battery (20) has reached a dangerous stage and output a warning signal indicating that the deterioration of the secondary battery 20 enters the dangerous stage. The control device 13 may transfer the warning signal indicating that the deterioration of the secondary battery 20 enters the dangerous stage to the upper control device.

The amount of change in the position where the inflection point occurs in the current curve may decrease (e.g., instantaneously decrease) due to another reason in addition to or other than an intensification of the deterioration of the secondary battery 20. In some embodiments, in order to prevent or lessen the chance of misrecognizing or not detecting that the deterioration of the secondary battery has intensified, a condition that the amount of change in the position where the inflection point occurs in the current curve is reduced (i.e., the condition of “(the second capacity value−the first capacity value)>(the third capacity value−the second capacity value)”) is continuously checked or checked at various times to determine whether the condition is satisfied a set number of times or more (e.g., a minimum number of times). If the control device 13 detects that the condition is satisfied at least the set minimum number of times, the control device 13 may determine that the amount of change in the position where the inflection point occurs in the current curve decreases, and may determine that the deterioration of the secondary battery 20 enters the dangerous stage.

The control device 13 may include at least one processor. The processor may refer to a data processing device (e.g., a microprocessor, a central processing unit (CPU), a processor core, a multiprocessor, an application-specific integrated circuit (ASIC), a field programmable gate array (FPGA), or the like) having a physically structured circuit to perform a function expressed by a code, command, or instructions included within a program. The program may be stored, for example, in the storage device 11 coupled to the control device.

The deterioration diagnosis device 10 may be integrated into a battery pack including the secondary battery 20. In this case, the control device 13 may be a portion of a battery management system (BMS) of the battery pack.

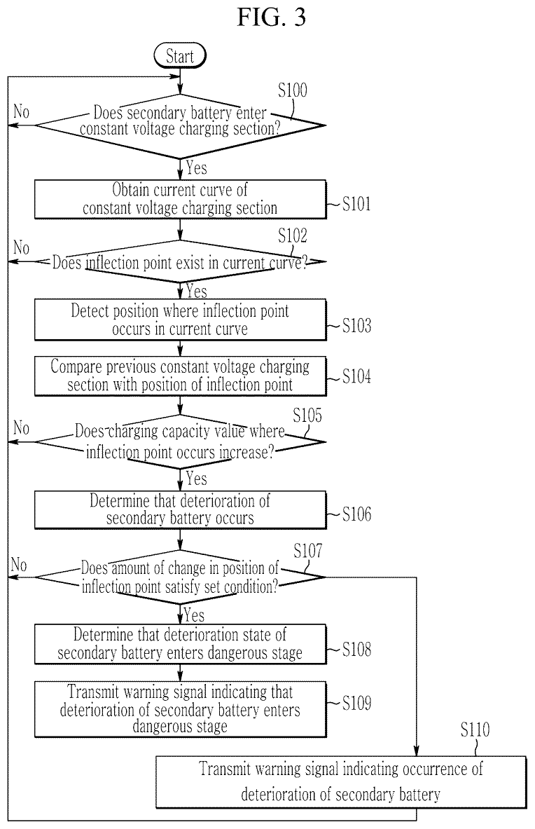

FIG. 3 is a flow diagram of a process for diagnosing deterioration of the secondary battery according to some embodiments. The method of FIG. 3 may be performed by the deterioration diagnosis device 10 described with reference to FIG. 1.

Referring to FIG. 3, a determination is made as to whether the secondary battery 20 enters the constant voltage charging section (S100). If the answer is YES, the deterioration diagnosis device 10 may obtain a current curve of the constant voltage charging section using current values measured from the secondary battery 20 during the constant voltage charging section (S101). The current curve may represent a change of the current according to a charging capacity of the secondary battery 20.

If the current curve is obtained in act S101, the deterioration diagnosis apparatus 10 may check (or confirm) whether an inflection point exists in the current curve (S102). In this regard, the deterioration diagnosis device 10 may obtain a differential current curve representing an instantaneous or infinitely small current change rate according to the charging capacity by differentiating the current curve by applying differential calculus to the current curve. The inflection point in the current curve may be converted or mapped to a peak point in the differential current curve. In some embodiments, the deterioration diagnosis device 10 may check whether the peak point exists in the differential current curve to check or determine whether the inflection point exists in the current curve.

If the inflection point exists in the current curve, the deterioration diagnosis device 10 may detect a position where the inflection point occurs in the current curve (e.g., a charging capacity value where the inflection point occurs) (S103). In this regard, the deterioration diagnosis device 10 may detect the peak point from the differential current curve obtained by differentiating the current curve, and may obtain a position where the peak point is detected in the differential current curve (e.g., a charging capacity value where the peak point is detected) as the position where the inflection point occurs in the current curve.

The deterioration diagnosis device 10 may diagnose a deterioration state of the secondary battery 20 based on detecting the inflection point position in act S103.

In this regard, the deterioration diagnosis device 10 may compare a previous constant voltage charging section in which the inflection point is detected in the current curve with the position of the inflection point to diagnose occurrence of the deterioration (S104). For example, the deterioration diagnosis device 10 may compare a position where the inflection point occurs in the current curve of a current constant voltage charging section with a position where the inflection point occurs in the current curve of a previous constant voltage charging section. Based on the result of the comparison in act S104, the deterioration diagnosis device 10 may determine whether the position where the inflection point occurs in the current curve (e.g., the charging capacity value where the inflection point occurs) increases compared with the previous one (S105). If it is determined that the charging capacity value where the inflection point occurs in the current curve increases compared with that of the previous constant voltage charging section, the deterioration diagnosis apparatus 10 may determine that the deterioration of the secondary battery 20 occurs due to an increase in the lithium precipitation and the resistance of the battery (S106).

For example, the deterioration diagnosis device 10 may check whether an amount of change in the position of the inflection point satisfies a set condition in order to check whether the deterioration state of the secondary battery 20 enters a dangerous stage (S107). With respect to act S107, the amount of change in the position of the inflection point may represent a value obtained by subtracting the charging capacity value where the inflection point occurs in the current curve of the previous constant voltage charging section from the charging capacity value where the inflection point occurs in the current curve of the current constant voltage charging section.

With respect to act S107, the set condition may include a condition in which the amount of change in the position of the inflection point decreases compared with the previous amount of change. The deterioration diagnosis device 10 may determine that the set condition is satisfied if the amount of change in the position of the inflection point decreases compared with the previous amount of change.

With respect to act S107, the set condition may include a condition where the amount of change in the position of the inflection point decreases compared with the amount of change in the position of the previous one occurs (e.g., continuously occurs) a set number of times or more. The deterioration diagnosis device 10 may determine that the set condition is satisfied if the amount of change in the position of the inflection point continuously decreases or decreases a set number of times during various constant voltage charging sections.

If it is determined that the amount of change in the position of the inflection point satisfies the set condition in act S107, the deterioration diagnosis device 10 may determine that the amount of change in the position where the inflection point occurs in the current curve decreases and the deterioration state of the secondary battery 20 enters the dangerous stage (S108). Thus, the deterioration diagnosis device 10 may transmit a warning signal (e.g., a first type of warning signal) indicating that the deterioration of the secondary battery 20 enters the dangerous stage to an upper control device (S109).

If it is determined that the amount of change in the position of the inflection point does not satisfy the set condition through the step S107, the deterioration diagnosis device 10 may transmit a warning signal (e.g., a second type of warning signal different form the first type) indicating the occurrence of deterioration of the secondary battery 20 to the upper control device (S110).

Although the present disclosure has been described above by limited embodiments and the drawings, the present disclosure is not limited thereto, and various modifications and variations may be made within an equivalent scope of the technical idea of the present disclosure and claims to be described below by those of ordinary skill in the art.

### DESCRIPTION OF SYMBOLS

10: deterioration diagnosis device
11: storage device
12: measurement device
13: control device
14: secondary battery

What is claimed is:

1. A device for detecting a condition of a secondary battery, comprising:
a measurement device configured to measure a current of the secondary battery; and
a control device configured to:
obtain a first current curve representing a relationship between a charging capacity and the current of the secondary battery based on a value of the current of the secondary battery measured during a first charging phase; and
detect the condition of the secondary battery based on a first position of a first point in the first current curve.

2. The device as claimed in claim 1, wherein the control device is further configured to:
perform a mathematical computation to the first current curve to obtain a second current curve; and
obtain the first position where the first point occurs in the first current curve based on a second position where a second point is detected in the second current curve.

3. The device of claim 2, wherein the mathematical computation includes applying differential calculus to the first current curve, wherein the second current curve includes a differential current curve, the first point includes an inflection point in the first current curve, and the second point includes a peak point in the differential current curve.

4. The device as claimed in claim 1, wherein the first position of the inflection point indicates a charging capacity value at which an inflection point occurs in the first current curve.

5. The device as claimed in claim 4, wherein the control device is further configured to:
perform an operation for obtaining the first current curve and detecting the first position of the first point in the first current curve for a plurality of charging phases including the first charging phase; and
detect occurrence of deterioration of the secondary battery by comparing a first charging capacity value where the first point occurs in the first current curve of the first charging phase with a second charging capacity value where the first point occurs in the first current curve of a previous charging phase.

6. The device as claimed in claim 5, wherein the control device is further configured to detect that the deterioration of the secondary battery occurs based on the first charging capacity value being greater than the second charging capacity value.

7. The device as claimed in claim 4, wherein the condition of the secondary battery includes deterioration of the secondary battery, wherein the control device is further configured to detect that a deterioration state of the secondary battery reaches a dangerous stage based on an amount of change in the first position of the inflection point.

8. The device as claimed in claim 7, wherein the control device is further configured to:
perform an operation for obtaining the first current curve and the first position of the first point in the first current curve for a plurality of charging phases including the first charging phase; and
calculate an amount of change in the first position by subtracting a second charging capacity value where the first point occurs in the first current curve of a previous charging phase from a first charging capacity value where the first point occurs in the first current curve of the first charging phase.

9. The device as claimed in claim 8, wherein the control device is further configured to detect that the deterioration state of the secondary battery reaches the dangerous stage based on detecting that the amount of change in the first position decreases compared to a second amount of change associated with the previous charging phase.

10. The device as claimed in claim 8, wherein the control device is further configured to detect that the deterioration state of the secondary battery reaches the dangerous stage based on detecting that the amount of change in the first position decreases a set number of times during a plurality of charging phases.

11. A battery pack comprising:
a secondary battery; and
the device for detecting the condition of the secondary battery according to claim 1.

12. A method for detecting a condition of a secondary battery, comprising:
obtaining a first current curve representing a relationship between a charging capacity and a current of the secondary battery based on a value of the current of the secondary battery measured during a first charging phase;
obtaining a first position of a first point in the first current curve; and
detecting the condition of the secondary battery based on the first position of the first point.

13. The method as claimed in claim 12, wherein the obtaining of the first position of the first point comprises:
performing a mathematical computation to the first current curve to obtain a second current curve;
detecting a second point in the second current curve; and
obtaining the first position of the first point based on a second position at which the second point is detected in the second current curve.

14. The method as claimed in claim 12, wherein the first position of the first point indicates a charging capacity value at which an inflection point occurs in the first current curve.

15. The method as claimed in claim 14, wherein obtaining the first current curve and obtaining the first position of the first point are performed for a plurality of charging phases including the first charging phase, and the detecting the condition comprises detecting deterioration of the secondary battery by comparing a first charging capacity value where the first point occurs in the first current curve of the first charging phase with a second charging capacity value where the first point occurs in the first current curve of a previous charging phase.

16. The method as claimed in claim 15, wherein the detecting the deterioration of the secondary battery is based on the first charging capacity value being greater than the second charging capacity value.

17. The method as claimed in claim 14, wherein the obtaining of the first current curve and the obtaining of the first position of the first point are performed for a plurality of charging phases including the first charging phase, and the detecting the condition comprises detecting that a deterioration state of the secondary battery reaches a dangerous stage based on an amount of change in the first position of the inflection point.

18. The method as claimed in claim 17, further comprising calculating the amount of change in the first position by subtracting a second charging capacity value where the inflection point occurs in the first current curve of a previous charging phase from a first charging capacity value where the first point occurs in the first current curve of the first charging phase.

19. The method as claimed in claim 17, wherein the detecting of the deterioration state comprises determining that the deterioration state of the secondary battery reaches the dangerous stage based on detecting that the amount of change in the first position decreases compared to a previous amount of change.

20. The method as claimed in claim 17, wherein the detecting of the deterioration state comprises determining that the deterioration state of the secondary battery reaches the dangerous stage based on detecting that the amount of change in the first position decreases a set number of times during a plurality of charging phases.
